(19) United States
(12) Patent Application Publication
(10) Pub. No.: US 2015/0085587 A1
(43) Pub. Date: Mar. 26, 2015

(54) PING-PONG BUFFER USING SINGLE-PORT MEMORY

(71) Applicant: LSI Corporation, San Jose, CA (US)

(72) Inventor: Venkat Rao Vallapaneni, Bangalore (IN)

(73) Assignee: LSI Corporation, San Jose, CA (US)

(21) Appl. No.: 14/231,417

(22) Filed: Mar. 31, 2014

(30) Foreign Application Priority Data
Sep. 25, 2013 (IN) 4352/CHE/2013

(51) Int. Cl. G11C 7/10; G11C 7/22; G11C 11/419

(52) U.S. Cl. CPC G11C 7/1039; G11C 11/419; G11C 7/222
USPC 365/189.02; 365/189.05

(57) ABSTRACT

A method of controlling a ping-pong buffer includes selectively providing one of a ping gated write clock signal and a ping gated read clock signal to a single-port ping buffer, and selectively providing a pong gated write clock signal or a pong gated read clock signal to a single-port pong buffer. A controller of a ping-pong buffer includes a ping multiplexer and a pong multiplexer. The ping multiplexer selectively provides a ping gated write clock signal or a ping gated read clock signal to a single-port ping buffer. The pong multiplexer selectively provides a pong gated write clock signal or a pong gated read clock signal to a single-port pong buffer. A ping-pong buffer system includes a ping buffer, a pong buffer, a ping multiplexer, and a pong multiplexer. The ping buffer and pong buffer each include a single-port memory.

### CROSS-REFERENCE TO RELATED APPLICATIONS

This application claims priority under 35 U.S.C. §119 from Indian Patent Application No. 4352/CHE/2013 filed in the Indian Patent Office on Sep. 25, 2013, the disclosure of which is incorporated herein by reference in its entirety.

### TECHNICAL FIELD

The present invention relates generally to electrical and electronic circuitry, and more particularly relates to buffer circuitry.

### BACKGROUND

Dual-port memory buffers are often used to transfer data from one clock domain to another clock domain. Each clock domain is typically synchronous to a different clock signal. However, the use of dual-port memory devices results in substantial increases in space requirements, input/output connections, and manufacturing costs.

### SUMMARY

In accordance with an embodiment of the invention, a method of controlling a ping-pong buffer includes selectively providing one of a ping gated write clock signal and a ping gated read clock signal to a single-port ping buffer. The single-port ping buffer is written in response to the ping gated write clock, and read in response to the ping gated read clock. The method also includes selectively providing one of a pong gated write clock signal and a pong gated read clock signal to a single-port pong buffer. The single-port pong buffer is written in response to the pong gated write clock, and read in response to the pong gated read clock. Other embodiments of the invention include but are not limited to being manifest as a controller for use in conjunction with a ping-pong buffer, and an electronic system. Additional and/or other embodiments of the invention are described in the following written description, including the claims, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a block diagram depicting at least a portion of an exemplary ping-pong buffer using dual-port SRAM;

FIGS. 2A-2C are block diagrams depicting illustrative embodiments of ping buffer logic and pong buffer logic suitable for use in the ping-pong buffer shown in FIG. 1;

FIG. 3 is a block diagram depicting at least a portion of an exemplary ping-pong buffer using single-port SRAM, according to an embodiment of the invention;

FIGS. 4A-4C are block diagrams depicting illustrative embodiments of ping buffer logic and pong buffer logic suitable for use in the ping-pong buffer shown in FIG. 3, according to embodiments of the invention;

FIG. 5 is a timing diagram depicting exemplary signal waveforms associated with the illustrative ping-pong buffer shown in FIG. 3, according to an embodiment of the invention;

FIG. 6 is a flowchart depicting at least a portion of an exemplary method detailing an operation of the illustrative ping-pong buffer shown in FIG. 3, according to an embodiment of the invention; and

FIG. 7 is a block diagram showing at least a portion of an exemplary machine in the form of a computing system configured to perform methods according to one or more embodiments disclosed herein.

It is to be appreciated that the drawings described herein are presented for illustrative purposes only. Moreover, common but well-understood elements and/or features that may be useful or necessary in a commercially feasible embodiment may not be shown in order to facilitate a less hindered view of the illustrated embodiments.

### DETAILED DESCRIPTION

Embodiments of the invention will be described herein in the context of illustrative ping-pong buffer circuits implemented utilizing SRAM. It should be understood, however, that embodiments of the invention are not limited to these or any other particular buffer circuit arrangements. Rather, embodiments of the invention are more broadly applicable to buffer circuits comprising single-port memory, without concern for whether the memory is embedded or standalone. In this regard, embodiments of the invention provide a buffer scheme that beneficially provides enhanced performance, reduced power consumption, and/or reduced space requirements, among other features, in a variety of memory arrangements and types, such as, for example, random access memory (RAM), SRAM, content addressable memory (CAM), flash memory, memory caches, register files, port buffer memories, and the like. Moreover, it will become apparent to those skilled in the art given the teachings herein that numerous modifications can be made to the illustrative embodiments shown that are within the scope of the claimed invention. That is, no limitations with respect to the embodiments shown and described herein are intended or should be inferred.

As a preliminary matter, for purposes of clarifying and describing embodiments of the invention, the following table provides a summary of certain acronyms and their corresponding definitions, as the terms are used herein:

Table of Acronym Definitions

| Acronym | Definition |
|---|---|
| SRAM | Static random access memory |
| RAM | Random access memory |
| CAM | Content addressable memory |
| ASIC | Application-specific integrated circuit |
| FIFO | First-in first-out |
| PCI | Peripheral component interconnect |
| PCIe | PCI express |
| AGP | Accelerated graphics port |
| RAID | Redundant array of independent disks |
| DRAM | Dynamic random access memory |
| VRAM | Video random access memory |

Dual-port memory buffers are used to transfer data from one clock domain to another clock domain. The circuitry in each clock domain is typically synchronous to a different clock signal. If improved performance is required or data is to be sent continuously, a ping-pong buffering scheme is used, in which two buffers are alternately written to (i.e., “filled”) or read from (i.e., “spilled”).

Application-specific integrated circuits (ASICs) are often used in conjunction with more than one clock domain, each of which is synchronous to a different clock signal. When data crosses from one clock domain to another clock domain, the data is resynchronized with the clock signal associated with the destination clock domain. Typically, asynchronous first-in first-out (FIFO) buffers are used to synchronize data passing between different clock domains, and these FIFOs are implemented using dual port memories. While data is written from one clock domain, data can be read from another clock domain in such a configuration. In addition, read and write pointers are synchronized to ensure data integrity. For proper synchronization of these pointers, the read pointers and write pointers are implemented using gray coding.

In some systems, data is transferred continuously. For example, in accordance with peripheral component interconnect express (PCIe) protocol, packet data transmission may be continuous. In typical asynchronous FIFO implementations, the FIFO is read or spilled, before the FIFO is completely written or filled. Thus, asynchronous FIFOs are not efficient for applications in which data is to be provided continuously.

PCIe is a high-speed expansion card format that connects a computer with its attached peripherals. PCIe was developed to replace peripheral component interconnect (PCI) and PCI-X expansion buses, as well as the accelerated graphics port (AGP) graphics card interface. PCIe allows data center managers to take advantage of networking technologies, such as, for example, Gigabit Ethernet, redundant array of independent disks (RAID), and Infiniband.

PCIe is a serial interface format, unlike PCI and PCI-X, which are parallel formats. Devices connected to a motherboard using PCIe have their own dedicated point-to-point connections. Each of these connections is referred to as a “lane” and is controlled by a switch. As a result of this architecture, connected devices do not need to share bandwidth over a single bus, as is the case when using PCI, which enables more scalable performance, lower latency, and higher data transfer rates. Condensing multiple parallel buses into one serial connection saves physical space in servers and workstations, which becomes important when rack space is limited.

For such systems, in which data is to be provided continuously, two types of configurations may be used. In a first so-called “fill-and-spill” configuration, a complete set of data is filled (i.e., written) into the FIFO, which is then spilled (i.e., read) continuously. However, while the FIFO is spilling data, the FIFO cannot be filled. Thus, this configuration provides a rather low-performance solution. For improved performance, a second so-called “ping-pong” buffering configuration is employed. In a ping-pong buffering configuration, while data is filled into either a ping buffer or a pong buffer, data can be concurrently spilled from the ping buffer or the pong buffer that is not being filled, which thereby achieves a substantial performance improvement.

The ping-pong buffer includes a pair of linked buffers that alternately act as input and output buffers. The basic idea is to use the ping buffer to receive data while reading and processing contents of the pong buffer, and to then swap the roles of both buffers. Using a pair of ping-pong buffers enables separate input and output processing buffers that can be stored in independent memory locations.

In the ping-pong buffer scheme, FIFO memory is only used for either a write (fill) operation or a read (spill) operation at any given time. The embodiments disclosed herein use single-port SRAM and multiplexed clock signals, in contrast to using dual-port SRAM. Additional modifications are made to the conventional dual-port memory ping-pong buffer schemes. The embodiments disclosed herein achieve significant reductions in cost, power and space requirements, among other features, when compared with conventional techniques.

As discussed above, asynchronous FIFOs are often used to transfer data from one clock domain to another clock domain, and these FIFOs are typically implemented using dual-port SRAM. If improved performance is required or data is to be sent continuously, as in the case of PCIe, for instance, where one packet is to be sent continuously, a ping-pong buffering scheme is preferably employed.

Since each ping-pong buffer is only used for either a read operation or a write operation at any given time, single-port SRAM is sufficient. The clock signals used for the read operation and write operation are provided by a clock multiplexer. Since buffer availability for spilling, which occurs after the buffer to be spilled is filled, is resynchronized to the clock signal associated with the destination clock domain, data is safe to spill to the destination clock domain.

Thus, one or more embodiments disclosed herein enable the use of single-port SRAM for transferring data between clock domains, clock signal multiplexing to allow selection of read and write clock signals, and gated clock signals as clock signal multiplexer inputs to avoid glitches in the clock signal multiplexer output when switching between clock domains.

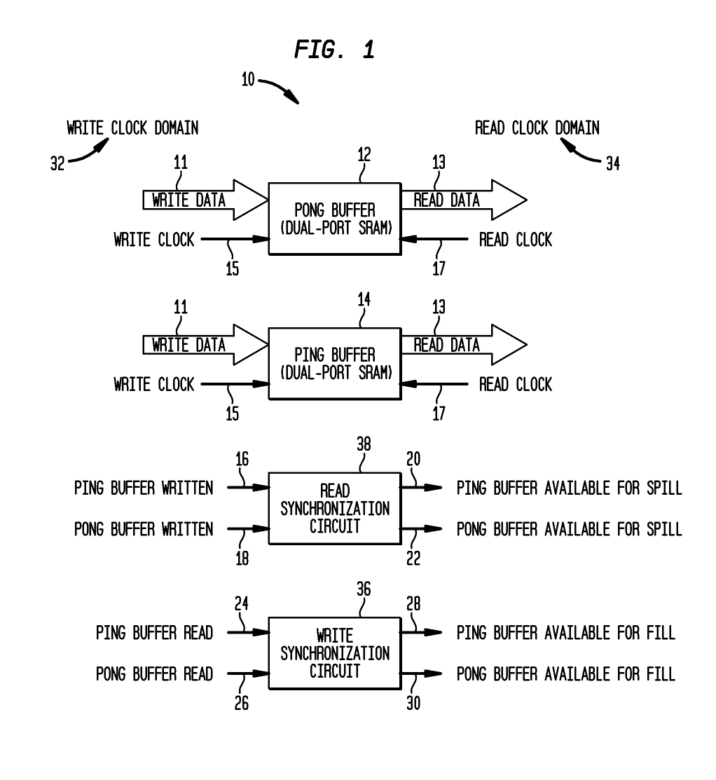

FIG. 1 is a block diagram depicting at least a portion of an exemplary ping-pong buffer circuit 10, which can be modified in accordance with embodiments of the invention. The buffer circuit 10 includes a write synchronization circuit 36, a read synchronization circuit 38, a dual-port SRAM pong buffer 12, and a dual-port SRAM ping buffer 14 configured in a manner for transferring data between a write clock domain 32 and a read clock domain 34. One or more write data signals 11, a write clock signal 15, and a read clock signal 17 are supplied to corresponding inputs of each of the buffers 12 and 14. One or more read data signals 13 are output by each of the buffers 12 and 14. A ping buffer written signal 16 and a pong buffer written signal 18 are supplied to corresponding inputs of the read synchronization circuit 38, and a ping buffer available for spill signal 20 and a pong buffer available for spill signal 22 are output by the read synchronization circuit 38. A ping buffer read signal 24 and a pong buffer read signal 26 are supplied to corresponding inputs of the write synchronization circuit 36, and a ping buffer available for fill signal 28 and a pong buffer available for fill signal 30 are output by the write synchronization circuit 36.

By way of example only and without limitation, an operation of the ping-pong buffer circuit 10 shown in FIG. 1 will now be described. With reference to FIG. 1, when the pong buffer 12 is available for filling, data from the write clock domain 32 is written into the pong buffer 12. Once data is completely written into the pong buffer 12, the pong buffer written signal 18 is asserted, which indicates that the pong buffer 12 has been filled. The pong buffer written signal 18 supplied to the read synchronization circuit 38 is synchronized to a read clock signal, which is associated with the read clock domain 34, to generate the pong buffer available for spill signal 22. The pong buffer available for spill signal 22 indicates that data in the pong buffer 12 just filled can be spilled into the read clock domain 34. While the data is spilled from the pong buffer 12 just filled, the ping buffer 14 can be used to fill data. Once the data is spilled from the pong buffer 12, the pong buffer read signal 26 is asserted. The pong buffer read signal 26 supplied to the write synchronization circuit 36 is synchronized to a write clock signal, which is associated with the write clock domain 32, to generate the pong buffer available for fill signal 30. The pong buffer available for fill signal 30 indicates that the pong buffer 12 that was filled is now spilled and thus can be refilled again.

Similarly, when the ping buffer 14 is available for filling, data from the write clock domain is written into the ping buffer 14. Once data is completely written into the ping buffer 14, the ping buffer written signal 16 is asserted, which indicates that the ping buffer 114 has been filled. The ping buffer written signal 16 supplied to the read synchronization circuit 38 is synchronized to the read clock signal, which is associated with the read clock domain 34, to generate the ping buffer available for spill signal 20. The ping buffer available for spill signal 20 indicates that data in the ping buffer 14 just filled can be spilled into the read clock domain 34. While the data is spilled from the ping buffer 14 just filled, the pong buffer 12 can be used to fill data. Once the data is spilled from the ping buffer 14, the ping buffer read signal 24 is asserted. The ping buffer read signal 24 supplied to the write synchronization circuit 36 is synchronized to the write clock signal, which is associated with the write clock domain 32, to generate the ping buffer available for fill signal 28. The ping buffer available for fill signal 28 indicates that the ping buffer 14 that was filled is now spilled and thus can be refilled again.

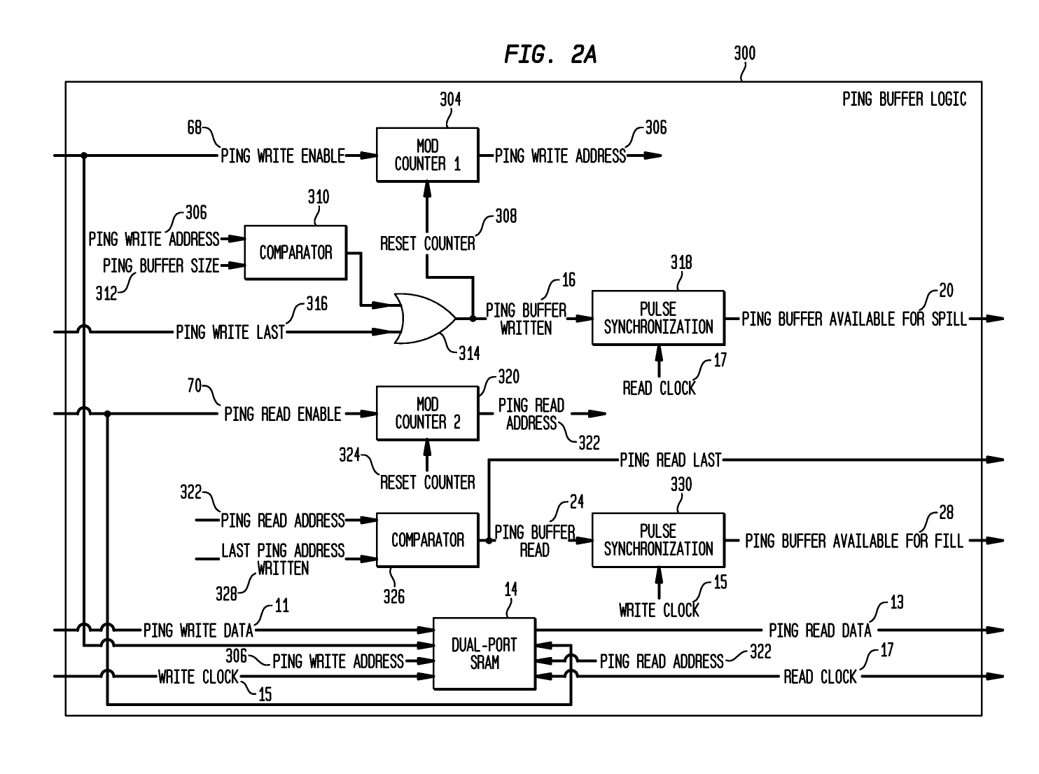

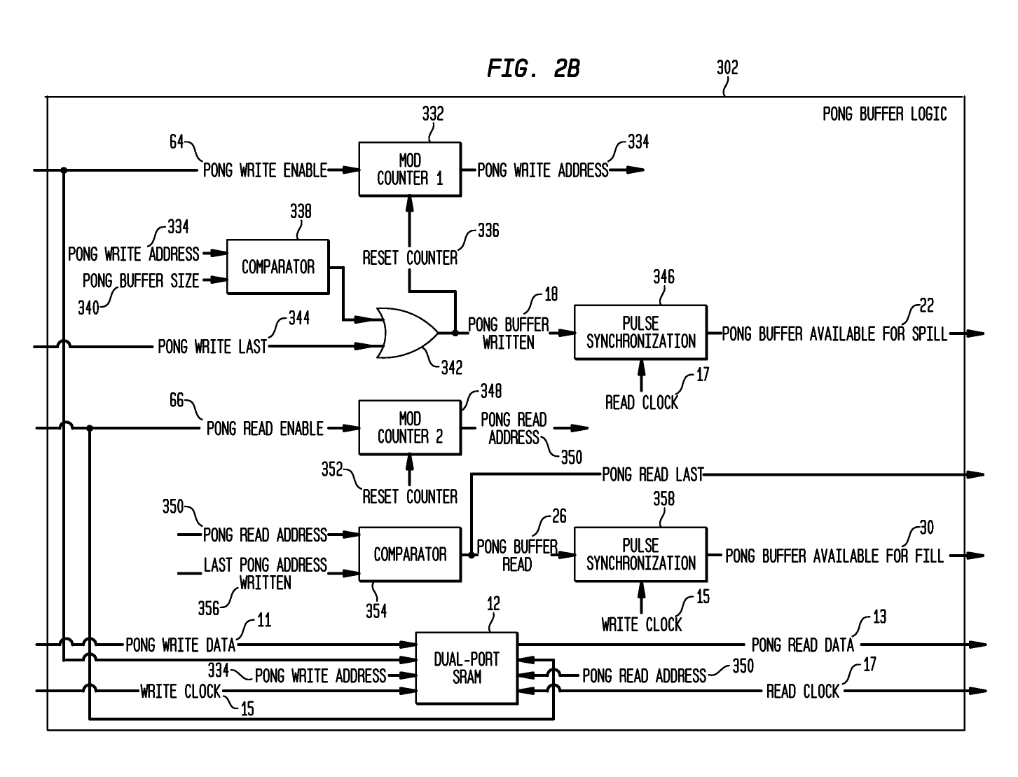

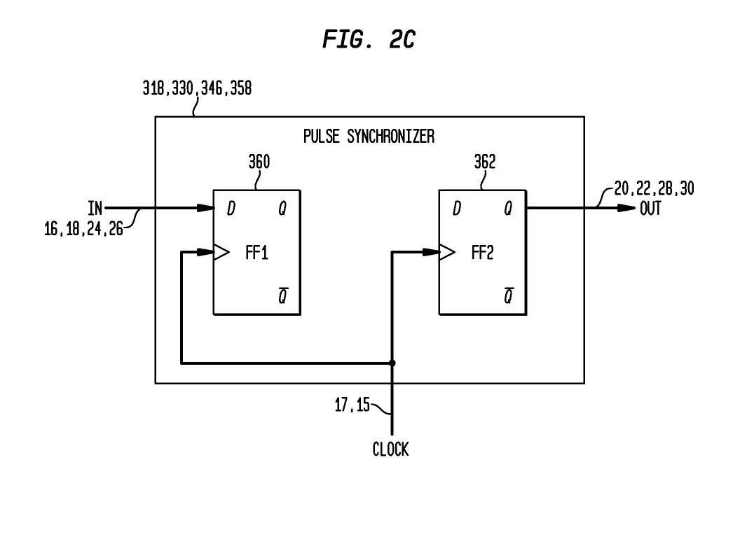

FIGS. 2A and 2B show a more detailed block diagram of the ping-pong buffer circuit shown in FIG. 1. FIG. 2A shows a ping buffer circuit 300 and FIG. 2B shows a pong buffer circuit 302. In FIG. 2A, a ping write enable signal 68 is coupled to the ping buffer 14 and a counter 304. The ping write enable signal 68 is asserted (high) in response to the ping buffer 14 being available for filling and data being available for writing. The counter 304 provides ping write address signals 306 in a counting sequence from 0×0, which is incremented for every cycle of the ping write enable signal 68. The ping write address signals 306 are reset to 0×0 in response to a reset counter signal 308, which is equivalent to the ping buffer written signal 16, being asserted (high). The ping write address signals 306 are provided to the ping buffer 14 and a comparator 310, which compares a ping buffer size signal 312 with the ping write address signals 304 and provides an output that is high in response to the compared signals being equal. The output of the comparator 310 is provided as an input to an OR gate 314, the remaining input of which is a ping write last signal 316. The output of the OR gate 314 is the ping buffer written signal 16, which is provided to a pulse synchronizer 318. The pulse synchronizer 318 synchronizes the ping buffer written signal 16 to generate the ping buffer available for spill signal 20 using the read clock signal 17.

A ping read enable signal 70 is coupled to the ping buffer 14 and a counter 320. The ping read enable signal 70 is asserted (high) in response to the ping buffer 14 being available for spilling and read data being able to be processed. The counter 320 provides ping read address signals 322 in a counting sequence from 0×0, which is incremented for every cycle of the ping read enable signal 70. The ping read address signals 322 are reset to 0×0 in response to a reset counter signal 324, which is equivalent to the ping buffer read signal 24, being asserted (high). The ping read address signals 322 are provided to the ping buffer 14 and a comparator 326, which compares a last ping address written signal 328 with the ping read address signals 322 and provides an output that is high in response to the compared signals being equal. The output of the comparator 326 is provided as the ping buffer read signal 24, which is provided to a pulse synchronizer 330. The pulse synchronizer 330 synchronizes the ping buffer read signal 24 to generate the ping buffer available for fill signal 28 using the write clock signal 15.

Similarly, in FIG. 2B, a pong write enable signal 64 is coupled to the pong buffer 12 and a counter 332. The pong write enable signal 64 is asserted (high) in response to the pong buffer 12 being available for filling and data being available for writing. The counter 332 provides pong write address signals 334 in a counting sequence from 0×0, which is incremented for every cycle of the pong write enable signal 64. The pong write address signals 334 are reset to 0×0 in response to a reset counter signal 335, which is equivalent to the pong buffer written signal 18, being asserted (high). The pong write address signals 334 are provided to the pong buffer 14 and a comparator 338, which compares a pong buffer size signal 340 with the pong write address signals 334 and provides an output that is high in response to the compared signals being equal. The output of the comparator 338 is provided as an input to an OR gate 342, the remaining input of which is a pong write last signal 344. The output of the OR gate 342 is the pong buffer written signal 18, which is provided to a pulse synchronizer 346. The pulse synchronizer 346 synchronizes the pong buffer written signal 18 to generate the pong buffer available for spill signal 22 using the read clock signal 17.

A pong read enable signal 66 is coupled to the pong buffer 12 and a counter 348. The pong read enable signal 68 is asserted (high) in response to the pong buffer 12 being available for spilling and read data being able to be processed. The counter 348 provides pong read address signals 350 in a counting sequence from 0×0, which is incremented for every cycle of the pong read enable signal 66. The pong read address signals 350 are reset to 0×0 in response to a reset counter signal 352, which is equivalent to the pong buffer read signal 26, being asserted (high). The pong read address signals 350 are provided to the pong buffer 12 and a comparator 354, which compares a last pong address written signal 356 with the pong read address signals 350 and provides an output that is high in response to the compared signals being equal. The output of the comparator 354 is provided as the pong buffer read signal 26, which is provided to a pulse synchronizer 358. The pulse synchronizer 358 synchronizes the pong buffer read signal 26 to generate the pong buffer available for fill signal 30 using the write clock signal 15.

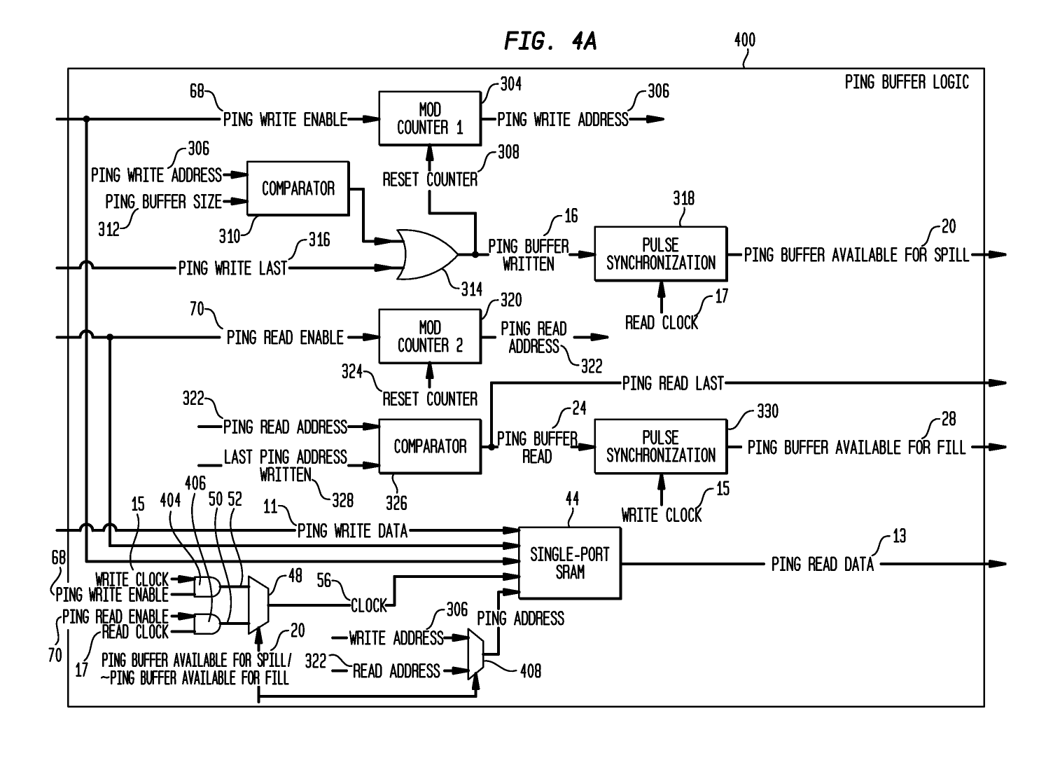

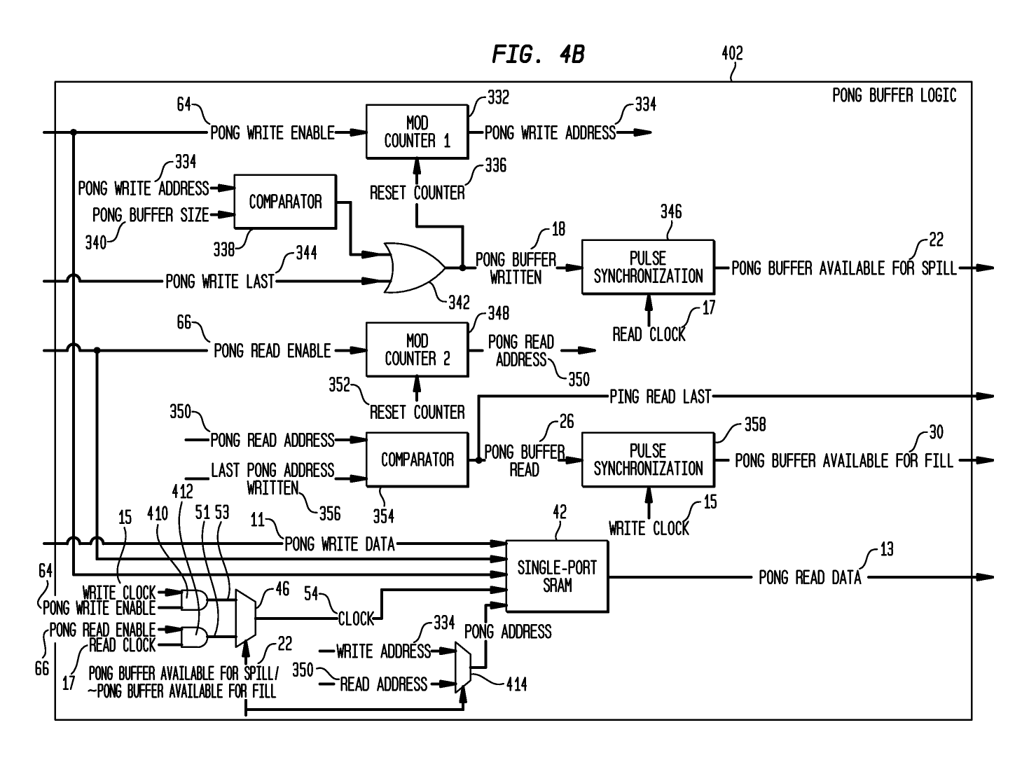

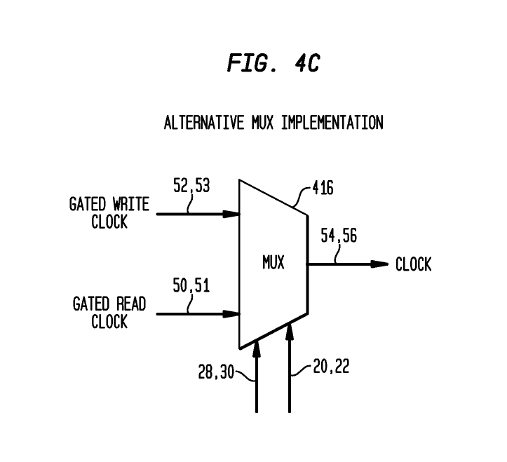

FIG. 2C is a schematic diagram depicting at least a portion of an exemplary pulse synchronizer suitable for use with embodiments of the invention. Specifically, FIG. 2C shows further detail concerning the pulse synchronizers 318, 330, 346, or 358 shown in FIGS. 2A and 2B, as well as in FIGS. 4A, and 4B described below. An input signal 16, 18, 24, or 26 is clocked through two flip-flops 360 and 362 using the clock signal 15 or 17 to generate a corresponding output signal 20, 22, 28, or 30. The output signal 20, 22, 28, or 30 will be indicative of the corresponding input signal 16, 18, 24, or 26, only synchronized with the clock signal 15 or 17. For example, if the circuit shown in FIG. 2C was used to implement the pulse synchronizer 318 shown in FIG. 2A, the input would be the ping buffer written signal 16, the output would be the ping buffer available for spill signal 20, and the clock signal would be the read clock signal 17.

As a consequence of the functional operation just described, any one of the buffers 12, 14 is used only for either filling or spilling during any given cycle, but is not used for both filling and spilling (i.e., both read and write operations) simultaneously. Since only a read operation or a write operation is used during any given clock cycle, dual-port SRAM is not required, and thus single-port SRAM is sufficient.

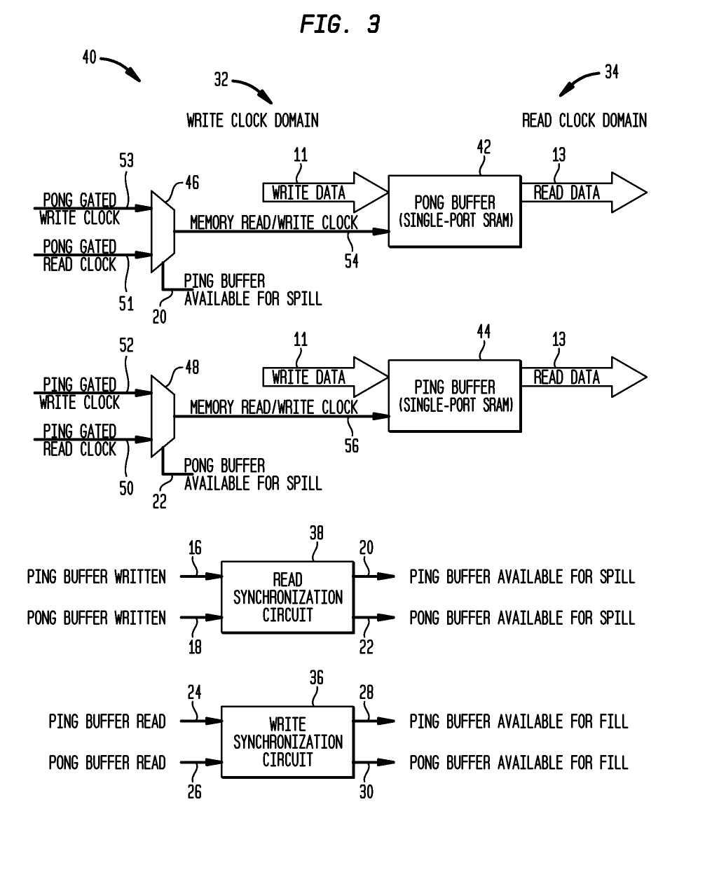

FIG. 3 is a block diagram depicting at least a portion of an exemplary ping-pong buffer circuit 40, according to an embodiment of the invention. The buffer circuit 40 includes a single-port SRAM pong buffer 42, a single-port SRAM ping buffer 44, a pong clock signal multiplexer 46, a ping clock signal multiplexer 48, a read synchronization circuit 38, and a write synchronization circuit 36. A ping gated read clock signal 50 and a ping gated write clock signal 52 are supplied to corresponding inputs of the ping clock signal multiplexer 48. Similarly, a pong gated read clock signal 51 and a pong gated write clock signal 53 are supplied to corresponding inputs of the pong clock signal multiplexer 46.

A first control signal, which in this embodiment is a ping buffer available for spill signal 20, controls the pong clock signal multiplexer 46, which provides a pong memory read/write clock signal 54 to the pong buffer 42. A second control signal, which in this embodiment is a pong buffer available for spill signal 22, controls the ping clock signal multiplexer 48, which provides a ping memory read/write clock signal 56 to the ping buffer 44. Write data signals 11 are supplied to corresponding inputs of each of the single-port pong and ping buffers 42 and 44, respectively, and read data signals 13 are output by each of the ping and pong buffers.

A ping buffer written signal 16 and a pong buffer written signal 18 are supplied to corresponding inputs of the read synchronization circuit 38, and the ping buffer available for spill signal 20 and the pong buffer available for spill signal 22 are output by the read synchronization circuit. Specifically, the ping buffer written signal 16 supplied to the read synchronization circuit 38 is synchronized to the read clock signal, which is associated with the read clock domain 34, to generate the ping buffer available for spill signal 20. The ping buffer available for spill signal 20 indicates that data in the ping buffer 44 just filled can be spilled into the read clock domain 34. Likewise, the pong buffer written signal 18 supplied to the read synchronization circuit 38 is synchronized to the read clock signal, which is associated with the read clock domain 34, to generate the pong buffer available for spill signal 22. The pong buffer available for spill signal 22 indicates that data in the pong buffer 42 just filled can be spilled into the read clock domain 34.

Similarly, a ping buffer read signal 24 and a pong buffer read signal 26 are supplied to corresponding inputs of the write synchronization circuit 36, and a ping buffer available for fill signal 28 and a pong buffer available for fill signal 30 are output by the write synchronization circuit.

The ping clock signal multiplexer 48 is used to select one of a ping gated read clock signal 50 and ping gated write clock signal 52 for generating a first memory read/write clock signal 56 supplied to the ping buffer 44 as a function of the pong buffer available for spill signal 22, depending on whether the ping buffer is used for filling (i.e., writing) or spilling (i.e., reading). To avoid glitches while, for example, the ping memory read/write clock signal 56 is switched between the ping gated read clock signal 50 and the ping gated write clock signal 52, these signals 50, 52 are gated, in accordance with one or more embodiments. The ping gated read clock signal 50 is gated with a ping read enable signal 70, and thus the ping gated read clock signal 50 is active when the ping buffer 44 is to be read. The ping read enable signal 70 is generated from system logic and is asserted when the ping buffer is available for spill and read data can be processed. The ping gated write clock signal 52 is gated with a ping write enable signal 64, and thus the ping gated write clock signal 52 is active when the ping buffer 44 is to be written. The ping write enable signal 64 is generated from system logic and is asserted when the ping buffer is available for fill and write data is available.

Similarly, the pong clock signal multiplexer 46 is used to select one of a pong gated read clock signal 51 and a pong gated write clock signal 53 for generating a second memory read/write clock signal 54 supplied to the pong buffer 42 as a function of the ping buffer available for spill signal 20, depending on whether the pong buffer is used for filling (writing) or spilling (reading). To avoid glitches while, for example, the pong memory read/write clock signal 54 is switched between the pong gated read clock signal 51 and the pong gated write clock signal 53, these signals 51, 53 are gated. More particularly, the pong gated read clock signal 51 is gated with a pong read enable signal 66, and thus the pong gated read clock signal is active when the pong buffer 42 is to be read. The pong gated write clock signal 53 is gated with a pong write enable signal 64, and thus the pong gated write clock signal is active when the pong buffer 42 is to be written.

Between read and write operations, there is at least two cycles of delay due to resynchronization of the ping buffer written signal 16 and pong buffer written signal 18 from the write clock domain 32 to the read clock domain 34. Similarly between read and write operations, there is at least two cycles of delay due to resynchronization of the ping buffer read signal 24 and pong buffer read signal 26 from the read clock domain 34 to the write clock domain 32. During this resynchronization period, no read or write operations occur in the buffers 42, 44, thereby gating the pong memory read/write clock signal 54 and the ping memory read/write clock signal 56. Since switching between the ping gated read clock signal 50 and the ping gated write clock signal 52 occurs during resynchronization, the ping clock signal multiplexer 48 is provided with gated clock signals 50, 52 while the clock signals are switched between read and write operations.

By using the ping clock signal multiplexer 46 and pong clock signal multiplexer 48, a single clock is provided to either of the buffers 42 and 44, which thus conserves area and power consumption in comparison to conventional ping-pong buffer arrangements implemented using dual-port SRAM. Additional overhead for the ping clock signal multiplexer 48 and pong clock signal multiplexer 46 is negligible when compared with the savings obtained due to the use of single-port SRAM buffers 46 and 48. These savings become even more substantial as ping-pong buffer size requirements increase.

FIGS. 4A and 4B show more detailed block diagrams of the illustrative ping-pong buffer circuit shown in FIG. 3. More particularly, FIG. 4A shows an exemplary ping buffer logic circuit 400 and FIG. 4B shows an exemplary pong buffer logic circuit 402, according to embodiments of the invention. In FIG. 4A, further detail concerning circuitry that generates the ping memory read/write clock signal 56, which is shown in FIG. 3, is provided. This circuitry includes an AND gate 404 that is used to combine the write clock signal 15 and ping write enable signal 68 to generate the ping gated write clock signal 52, and an AND gate 406 that is used to combine the read clock signal 17 and ping read enable signal 70 to generate the ping gated read clock signal 50. In addition, a multiplexer 408 is used to selectively provide either the ping read address 322 or ping write address 306 to the ping buffer 44 in response to the ping buffer available for spill signal 20. If the read clock signal 17 has a higher frequency than the write clock signal 15, the multiplexer 48 is controlled by the ping buffer available for spill signal 20. However, if the read clock signal 17 has a lower frequency than the write clock signal 15, the multiplexer 48 is controlled by an inverted or active low version of the ping buffer available for fill signal 28.

Similarly, in FIG. 4B, further detail concerning circuitry that generates the pong memory read/write clock signal 54, which is shown in FIG. 3, is provided. This circuitry includes an AND gate 410 that is used to combine the write clock signal 15 and pong write enable signal 64 to generate the pong gated write clock signal 53, and an AND gate 412 that is used to combine the read clock signal 17 and pong read enable signal 66 to generate the pong gated read clock signal 51. In addition, a multiplexer 414 is used to selectively provide either the pong read address 350 or pong write address 334 to the pong buffer 42 in response to the pong buffer available for spill signal 22. If the read clock signal 17 has a higher frequency than the write clock signal 15, the multiplexer 46 is controlled by the pong buffer available for spill signal 22. However, if the read clock signal 17 has a lower frequency than the write clock signal 15, the multiplexer 46 is controlled by an inverted or active low version of the pong buffer available for fill signal 30.

FIG. 4C shows an alternative embodiment of a circuit to provide the pong memory read/write clock signal 54 or ping memory read/write clock signal 56, which includes a multiplexer 416 that selectively provides the gated write signals 52 or 53 or the gated read signals 50 or 51 as the pong memory read/write clock signal 54 or ping memory read/write clock signal 56 in response to the buffer available for fill signal 28 or 30 or the buffer available for spill signal 20 or 22. For example, if the circuit shown in FIG. 4C was used in the circuit shown in FIG. 4A, the ping gated write clock signal 52 and the ping gated read clock signal 50 would be coupled to inputs of the multiplexer 416, the output of the multiplexer 416 would be the ping memory read/write clock signal 56, and the ping buffer available for fill signal 28 and the ping buffer available for spill signal 20 would be used to selectively control the output of the multiplexer 416. As another example, if the circuit shown in FIG. 4C was used in the circuit shown in FIG. 4B, the pong gated write clock signal 53 and the pong gated read clock signal 51 would be coupled to inputs of the multiplexer 416, the output of the multiplexer 416 would be the pong memory read/write clock signal 54, and the pong buffer available for fill signal 30 and the pong buffer available for spill signal 22 would be used to selectively control the output of the multiplexer 416.

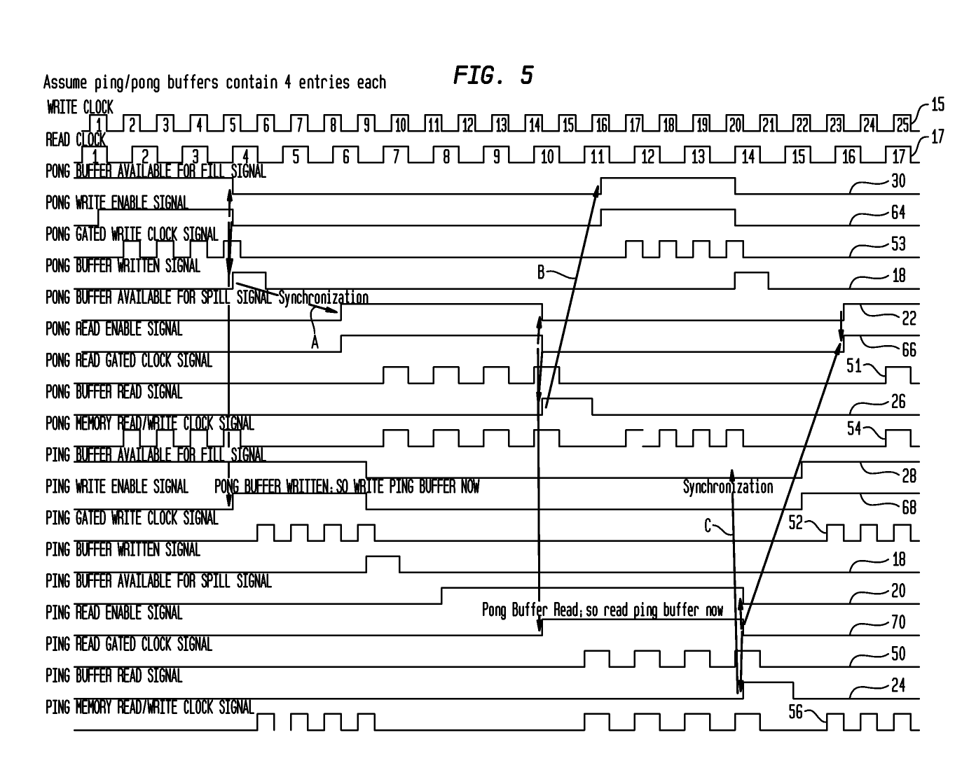

FIG. 5 is a timing diagram showing an operation of certain signals associated with the illustrative ping-pong buffer circuit 40 shown in FIG. 3, according to an embodiment of the invention. In the illustrative timing diagram of FIG. 5, one or more of the depicted signals transition between a logic low level (e.g., logic “0” or ground) and a logic high level (e.g., logic “1” or VDD), or vice versa, as will become apparent to those skilled in the art. It is to be appreciated that embodiments of the invention are not limited to any specific voltages used to define the logic low and logic high levels. For the example shown in FIG. 2, both the ping buffer 42 and pong buffer 44 include four memory locations, although embodiments of the invention are not limited to any specific size of the buffers 42, 44. In response to the pong buffer available for fill signal 30 being active (e.g., high), the pong buffer is written during cycles 1-5 of the write clock signal 15. During this time, the pong write enable signal 64 is active (high) and memory locations in the pong buffer are written on rising edges of the pong gated write clock signal 53.

In response to the pong buffer available for fill signal 30 being inactive (e.g., low) the ping buffer 44 is written during cycles 5-9 of the write clock signal 15. During this period, the pong write enable signal 68 is active (e.g., high), and write operations are performed on rising edges of the ping gated write clock signal 52, following which the ping buffer written signal 18 transitions to be active (e.g., high).

During cycles 6-11 of the read clock signal 17, the pong buffer 42 is read in response to the pong buffer available for spill signal 22 being active (e.g., high). During this period, the pong read enable signal 66 is active (e.g., high), and read operations are performed on rising edges of the pong gated read clock signal 51, following which the pong buffer read signal 26 transitions to be active (e.g., high).

In response to the pong buffer available for fill signal 30 being active (e.g., high), the pong buffer is again written during cycles 16-21 of the write clock signal 15. During this time, the pong write enable signal 64 is active (e.g., high) and memory locations in the pong buffer are written on rising edges of the pong gated write clock signal 53.

During cycles 10-15 of the read clock signal 17, the ping buffer is read in response to the ping buffer available for spill signal 20 being active (e.g., high). During this period, the ping read enable signal 70 is active (e.g., high), and read operations are performed in response to the rising edge of the ping memory read/write clock signal 56, following which the ping buffer read signal 24 transitions to be active (e.g., high).

In response to the pong buffer available for fill signal 30 transitioning to inactive (e.g., low), the ping buffer is written during at least cycles 22-25 of the write clock signal 15. During this period, the ping write enable signal 68 is active (e.g., high), and write operations are performed in response to rising edges of the ping gated write clock signal 52, following which the ping buffer written signal 18 transitions to be active (e.g., high).

During at least cycles 16-17 of the read clock signal 17, the pong buffer is read in response to the pong buffer available for spill signal 22 being active (e.g., high). During this period, the pong read enable signal 66 is active (e.g., high), and read operations are performed on rising edges of the pong gated read clock signal 51.

Arrow A in FIG. 5 represents resynchronization of the pong buffer written signal 18 to generate the pong buffer available for spill signal 22 in the read clock domain 34 using the read clock signal 17 by the read synchronization circuit 38 shown in FIG. 3. Arrow B in FIG. 5 represents resynchronization of the pong buffer read signal 26 to generate the pong buffer available for fill signal 30 in the write clock domain 32 using the write clock signal 15 by the write synchronization circuit 36 shown in FIG. 3. Arrow C in FIG. 5 represents resynchronization of the ping buffer read signal 24 as the ping buffer available for fill signal 28 in the write clock domain 32 using the write clock signal 15 by the write synchronization circuit 36 shown in FIG. 3.

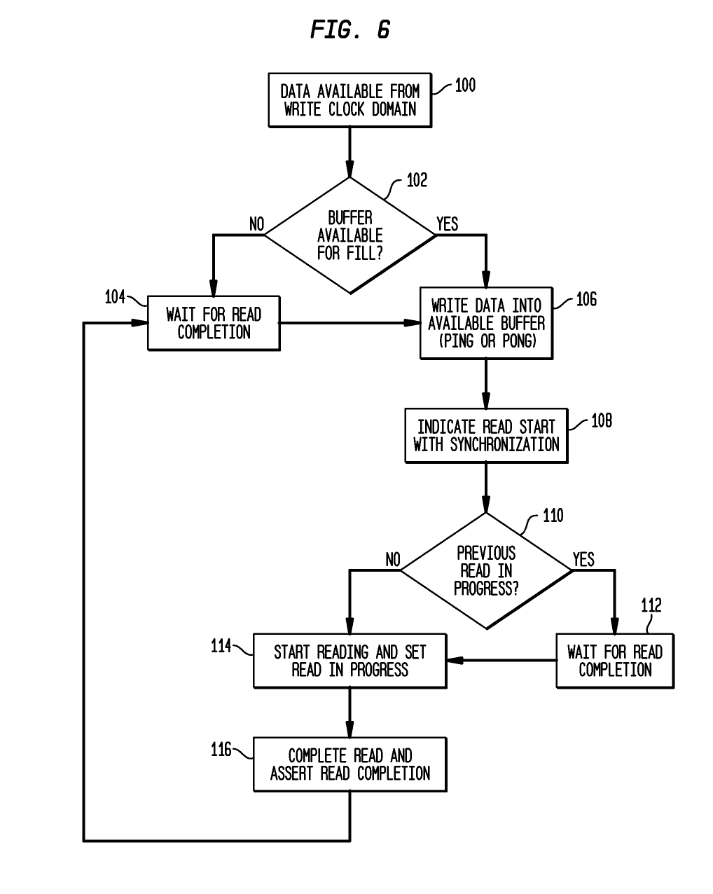

FIG. 6 is a flowchart depicting an exemplary operation of the illustrative ping-pong buffer circuit 40 shown in FIG. 3, according to an embodiment of the invention. With reference to FIG. 6, data is available in the write clock domain in step 100, and if either the ping buffer or pong buffer is available for being filled in step 102, the method proceeds to write either an available ping buffer or pong buffer in step 106. If neither the ping buffer nor pong buffer is available for being filled in step 102, then the process waits for completion of read operations in step 104 and proceeds to write data into either the ping buffer or the pong buffer in step 106. The remaining process flow arrows depicted in FIG. 6 show event sequences in the operation of the ping-pong buffer.

In step 108, the method starts a read operation with resynchronization in the read clock domain. If there is a previous read operation in progress in step 110, the method waits for completion of the read operation in step 112 and then proceeds to begin a new read operation in step 114. If there is no previous read operation in progress in step 110, the method proceeds to begin the new read operation in step 114 without waiting. Upon completion of the new read operation in step 116, the method asserts a read completion signal, which is either the pong buffer available for fill signal or the ping buffer available for fill signal.

While a ping-pong buffer has been described in various embodiments of the invention, embodiments of the invention are not limited thereto. Any suitable form of implementing the ping-pong buffer in accordance with one or more embodiments disclosed herein is contemplated to be within the scope of this disclosure. For example, each of the ping buff and pong buffer can be implemented in hardware, in software, or as a combination of hardware and software (e.g., firmware), as will become apparent to those skilled in the art given the teachings herein.

Furthermore, alternative embodiments may include more than two buffers, and/or buffers implemented using any other type of electronic storage element that can be written to and read from, such as, but not limited to, dynamic random access memory (DRAM), video random access memory (VRAM), disc drives, and the like. In addition, read and/or write operations may be performed in response to falling edges of a corresponding clock signal, or rising and falling clock edges, according to one or more embodiments. As another alternative, the ping-pong buffer could be implemented using a microprocessor, microcontroller, ASIC, digital circuitry, analog circuitry, and/or a combination thereof.

As will be appreciated by one skilled in the art, aspects of the present invention may be embodied as a system, method or computer program product. Accordingly, embodiments of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, at least a portion of embodiments of the invention may take the form of a computer program product embodied in one or more computer readable medium(s) having computer readable program code embodied thereon.

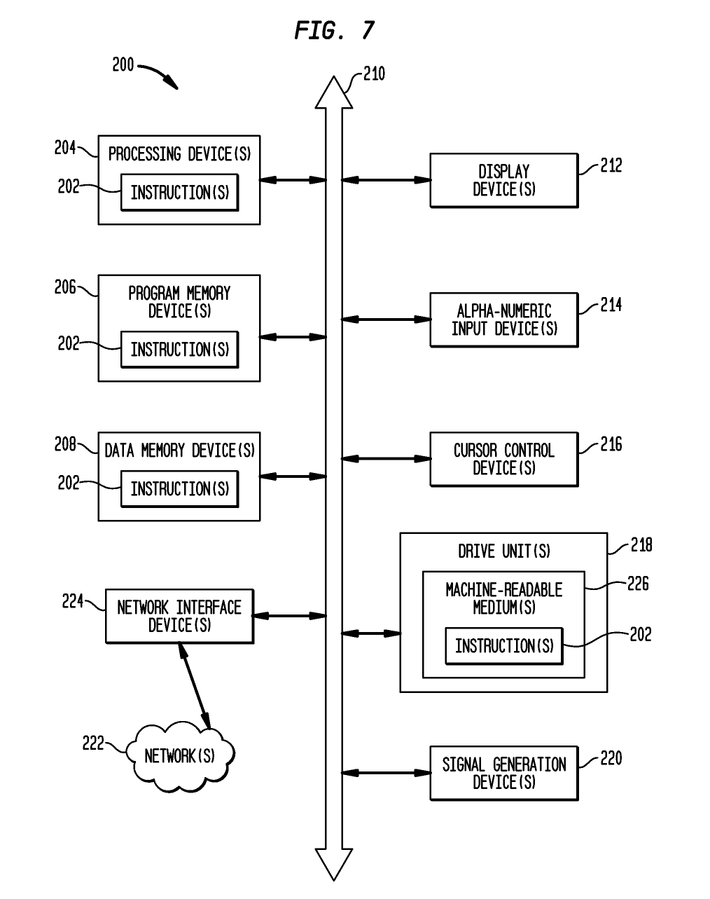

One or more embodiments of the invention, or elements thereof, can be implemented in the form of an apparatus including a memory and at least one processor that is coupled to the memory and operative to perform exemplary method steps, such as, for example, the exemplary methods steps shown in FIG. 7.

One or more embodiments of the invention, or a portion thereof, make use of software running on a general purpose computer or workstation. By way of example only and without limitation, FIG. 7 is a block diagram of an embodiment of a machine in the form of a computing system 200, within which is a set of instructions 202 that, when executed, cause the machine to perform any one or more of the methodologies according to embodiments of the invention. In one or more embodiments, the machine operates as a standalone device; in one or more other embodiments, the machine is connected (e.g., via one or more networks 222) to other machines. In a networked implementation, the machine operates in the capacity of a server or a client user machine in a server-client user network environment. Exemplary implementations of the machine as contemplated by embodiments of the invention include, but are not limited to, a server computer, client user computer, personal computer (PC), tablet PC, personal digital assistant (PDA), cellular telephone, mobile device, palmtop computer, laptop computer, desktop computer, communication device, personal trusted device, web appliance, network router, switch or bridge, or any machine capable of executing a set of instructions (sequential or otherwise) that specify actions to be taken by that machine.

The computing system 200 includes a processing device(s) 204 (e.g., a central processing unit (CPU), a graphics processing unit (GPU), or both), program memory device(s) 206, and data memory device(s) 208, which communicate with each other via a bus 210. The computing system 200 further includes display device(s) 212 (e.g., liquid crystals display (LCD), flat panel, solid state display, or cathode ray tube (CRT)). The computing system 200 includes input device(s) 214 (e.g., a keyboard), cursor control device(s) 216 (e.g., a mouse), disk drive unit(s) 218, signal generation device(s) 220 (e.g., a speaker or remote control), and network interface device(s) 224, operatively coupled together, and/or with other functional blocks, via bus 210.

The disk drive unit(s) 218 includes machine-readable medium(s) 226, on which is stored one or more sets of instructions 202 (e.g., software) embodying any one or more of the methodologies or functions herein, including those methods illustrated herein. The instructions 202 may also reside, completely or at least partially, within the program memory device(s) 206, the data memory device(s) 208, and/or the processing device(s) 204 during execution thereof by the computing system 200. The program memory device(s) 206 and the processing device(s) 204 also constitute machine-readable media. Dedicated hardware implementations, such as but not limited to ASICs, programmable logic arrays, and other hardware devices can likewise be constructed to implement methods described herein. Applications that include the apparatus and systems of various embodiments broadly comprise a variety of electronic and computer systems. Some embodiments implement functions in two or more specific interconnected hardware modules or devices with related control and data signals communicated between and through the modules, or as portions of an ASIC. Thus, the example system is applicable to software, firmware, and/or hardware implementations.

The term “processing device” as used herein is intended to include any processor, such as, for example, one that includes a CPU (central processing unit) and/or other forms of processing circuitry. Further, the term “processing device” may refer to more than one individual processor. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the display device(s) 212, input device(s) 214, cursor control device(s) 216, signal generation device(s) 220, etc., can be collectively referred to as an “input/output interface,” and is intended to include one or more mechanisms for inputting data to the processing device(s) 204, and one or more mechanisms for providing results associated with the processing device(s). Input/output or I/O devices (including but not limited to keyboards (e.g., alpha-numeric input device(s) 214, display device(s) 212, and the like) can be coupled to the system either directly (such as via bus 210) or through intervening input/output controllers (omitted for clarity).

In an integrated circuit implementation of one or more embodiments of the invention, multiple identical die are typically fabricated in a repeated pattern on a surface of a semiconductor wafer. Each such die may include a device described herein, and may include other structures and/or circuits. The individual dies are cut or diced from the wafer, then packaged as integrated circuits. One skilled in the art would know how to dice wafers and package die to produce integrated circuits. Any of the exemplary circuits or method illustrated in the accompanying figures, or portions thereof, may be part of an integrated circuit. Integrated circuits so manufactured are considered part of this invention.

An integrated circuit in accordance with the embodiments of the present invention can be employed in essentially any application and/or electronic system in which buffers are utilized. Suitable systems for implementing one or more embodiments of the invention include, but are not limited, to personal computers, interface devices (e.g., interface networks, high-speed memory interfaces (e.g., DDR3, DDR4), etc.), data storage systems (e.g., RAID system), data servers, etc. Systems incorporating such integrated circuits are considered part of embodiments of the invention. Given the teachings provided herein, one of ordinary skill in the art will be able to contemplate other implementations and applications.

In accordance with various embodiments, the methods, functions or logic described herein is implemented as one or more software programs running on a computer processor. Dedicated hardware implementations including, but not limited to, application specific integrated circuits, programmable logic arrays and other hardware devices can likewise be constructed to implement the methods described herein. Further, alternative software implementations including, but not limited to, distributed processing or component/object distributed processing, parallel processing, or virtual machine processing can also be constructed to implement the methods, functions or logic described herein.

The embodiment contemplates a machine-readable medium or computer-readable medium containing instructions 202, or that which receives and executes instructions 202 from a propagated signal so that a device connected to a network environment 222 can send or receive voice, video or data, and to communicate over the network 222 using the instructions 202. The instructions 202 are further transmitted or received over the network 222 via the network interface device(s) 224. The machine-readable medium also contains a data structure for storing data useful in providing a functional relationship between the data and a machine or computer in an illustrative embodiment of the systems and methods herein.

While the machine-readable medium 202 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding, or carrying a set of instructions for execution by the machine and that cause the machine to perform anyone or more of the methodologies of the embodiment. The term “machine-readable medium” shall accordingly be taken to include, but not be limited to: solid-state memory (e.g., solid-state drive (SSD), flash memory, etc.); read-only memory (ROM), or other non-volatile memory; random access memory (RAM), or other re-writable (volatile) memory; magneto-optical or optical medium, such as a disk or tape; and/or a digital file attachment to e-mail or other self-contained information archive or set of archives is considered a distribution medium equivalent to a tangible storage medium. Accordingly, the embodiment is considered to include anyone or more of a tangible machine-readable medium or a tangible distribution medium, as listed herein and including art-recognized equivalents and successor media, in which the software implementations herein are stored.

It should also be noted that software, which implements the methods, functions and/or logic herein, are optionally stored on a tangible storage medium, such as: a magnetic medium, such as a disk or tape; a magneto-optical or optical medium, such as a disk; or a solid state medium, such as a memory card or other package that houses one or more read-only (non-volatile) memories, random access memories, or other re-writable (volatile) memories. A digital file attachment to e-mail or other self-contained information archive or set of archives is considered a distribution medium equivalent to a tangible storage medium. Accordingly, the disclosure is considered to include a tangible storage medium or distribution medium as listed herein and other equivalents and successor media, in which the software implementations herein are stored.

As previously stated, although the specification describes components and functions implemented in accordance with embodiments of the invention with reference to particular standards and protocols, the embodiments are not limited to such standards and protocols.

The illustrations of embodiments of the invention described herein are intended to provide a general understanding of the structure of various embodiments, and they are not intended to serve as a complete description of all the elements and features of apparatus and systems that might make use of the structures described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

In the foregoing description of the embodiments, various features are grouped together in a single embodiment for the purpose of streamlining the disclosure. This method of disclosure is not to be interpreted as reflecting that the claimed embodiments have more features than are expressly recited in each claim. Rather, as the following claims reflect, inventive subject matter lies in less than all features of a single embodiment. Thus the following claims are hereby incorporated into the Detailed Description, with each claim standing on its own as a separate example embodiment.

The abstract is provided to comply with 37 C.F.R. §1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of the invention provided herein, one of ordinary skill in the art will be able to contemplate other implementations and applications of the techniques of the invention. Although illustrative embodiments of the invention have been described herein with reference to the accompanying drawings, it is to be understood that the invention is not limited to those precise embodiments, and that various other changes and modifications are made therein by one skilled in the art without departing from the scope of the appended claims.

What is claimed is:

1. A method of controlling a ping-pong buffer, the method comprising:
providing, selectively, one of a ping gated write clock signal and a ping gated read clock signal to a single-port ping buffer, the single-port ping buffer being written in response to the ping gated write clock signal, the single-port ping buffer being read in response to the ping gated read clock signal; and
providing, selectively, one of a pong gated write clock signal and a pong gated read clock signal to a single-port pong buffer, the single-port pong buffer being written in response to the pong gated write clock signal, the single-port pong buffer being read in response to the pong gated read clock signal.

2. The method of claim 1, further comprising:
providing the ping gated write clock signal based on a write clock signal and a ping write enable signal; and
providing the ping gated read clock signal based on a read clock signal and a ping read enable signal.

3. The method of claim 1, further comprising:
providing the pong gated write clock signal based on a write clock signal and a pong write enable signal; and
providing the pong gated read clock signal based on a read clock signal and a pong read enable signal.

4. The method of claim 1, further comprising:
providing, selectively, one of the pong gated write clock signal and the pong gated read clock signal to the pong buffer in response to a first control signal, the first control signal indicating that the ping buffer has been written; and
synchronizing the first control signal using a read clock signal.

5. The method of claim 1, further comprising:
providing, selectively, one of the ping gated write clock signal and the ping gated read clock signal to the ping buffer in response to a first control signal, the first control signal indicating that the pong buffer has been written; and
synchronizing the first control signal using a read clock signal.

6. The method of claim 1, further comprising:
providing a first control signal based on a ping buffer written signal;
synchronizing the first control signal using a read clock signal, the ping buffer written signal being synchronous to a write clock signal, the first control signal and the ping buffer written signal indicating that the ping buffer has been written;
providing a second control signal based on a pong buffer written signal; and
synchronizing the second control signal using the read clock signal, the pong buffer written signal being synchronous to the write clock signal, the second control signal and the pong buffer written signal indicating that the pong buffer has been written.

7. The method of claim 1, further comprising:
providing a first control signal based on a ping buffer read signal;
synchronizing the first control signal using a write clock signal, the ping buffer read signal being synchronous to a read clock signal, the first control signal and the ping buffer read signal indicating that the ping buffer has been read;
providing a second control signal based on a pong buffer read signal; and
synchronizing the second control signal to the write clock signal, the pong buffer read signal being synchronous to the read clock signal, the second control signal and the pong buffer read signal indicating that the pong buffer has been read.

8. A controller for use in conjunction with a ping-pong buffer, the controller comprising:
a first multiplexer, the first multiplexer selectively providing one of a ping gated write clock signal and a ping gated read clock signal to a single-port ping buffer, the single-port ping buffer being written in response to the ping gated write clock signal, the single-port ping buffer being read in response to the ping gated read clock signal; and
a second multiplexer, the second multiplexer selectively providing one of a pong gated write clock signal and a pong gated read clock signal to a single-port pong buffer, the single-port pong buffer being written in response to the pong gated write clock signal, the single-port pong buffer being read in response to the pong gated read clock signal.

9. The controller as defined by claim 8, wherein the ping gated write clock signal is generated based on a write clock signal and a ping write enable signal, and wherein the ping gated read clock signal is generated based on a read clock signal and a ping read enable signal.

10. The controller as defined by claim 8, wherein the pong gated write clock signal is generated based on a write clock signal and a pong write enable signal, and wherein the pong gated read clock signal is generated based on a read clock signal and a pong read enable signal.

11. The controller as defined by claim 8, wherein the second multiplexer selectively provides one of the pong gated write clock and the pong gated read clock to the single-port pong buffer in response to a first control signal, the first control signal indicating that the ping buffer has been written, the first control signal being synchronous to a read clock signal.

12. The controller as defined by claim 8, wherein the first multiplexer selectively provides one of the ping gated write clock and the ping gated read clock to the single-port ping buffer in response to a first control signal, the first control signal indicating that the pong buffer has been written, the first control signal being synchronous to a read clock signal.

13. The controller as defined by claim 8, further comprising a read synchronizer, the read synchronizer providing a first control signal based on a ping buffer written signal, the first control signal being synchronous to a read clock signal, the ping buffer written signal being synchronous to a write clock signal, the first control signal and the ping buffer written signal indicating that the single-port ping buffer has been written, the read synchronizer providing a second control signal based on a pong buffer written signal, the second control signal being synchronous to the read clock signal, the pong buffer written signal being synchronous to the write clock signal, the second control signal and the pong buffer written signal indicating that the single-port pong buffer has been written.

14. The controller as defined by claim 13, wherein the first control signal comprises a ping buffer available for spill signal, and wherein the second control signal comprises a pong buffer available for spill signal.

15. The controller as defined by claim 8, further comprising a write synchronizer, the write synchronizer providing a first control signal based on a ping buffer read signal, the first control signal being synchronous to a write clock signal, the ping buffer read signal being synchronous to a read clock signal, the first control signal and the ping buffer read signal indicating that the single-port ping buffer has been read, the write synchronizer providing a second control signal based on a pong buffer read signal, the second control signal being synchronous to the write clock signal, the pong buffer read signal being synchronous to the read clock signal, the second control signal and the pong buffer read signal indicating that the single-port pong buffer has been read.

16. The controller as defined by claim 15, wherein the first control signal comprises a ping buffer available for fill signal, and the second control signal comprises a pong buffer available for fill signal.

17. The controller as defined by claim 15, wherein at least a portion of the controller is fabricated in at least one integrated circuit.

18. A system including at least one ping-pong buffer, the at least one ping-pong buffer comprising:
a ping buffer comprising a first single-port memory device;
a pong buffer comprising a second single-port memory device;
a ping multiplexer, the ping multiplexer selectively providing one of a ping gated write clock signal and a ping gated read clock signal to the ping buffer, the ping buffer being written in response to the ping gated write clock, the ping buffer being read in response to the ping gated read clock signal; and
a pong multiplexer, the pong multiplexer selectively providing one of a pong gated write clock signal and a pong gated read clock signal to the pong buffer, the pong buffer being written in response to the pong gated write clock signal, the pong buffer being read in response to the pong gated read clock signal.

19. The system of claim 18, wherein the ping gated write clock signal is generated as a function of a write clock signal and a ping write enable signal, and the ping gated read clock signal is generated as a function of a read clock signal and a ping read enable signal.

20. The system of claim 18, wherein the pong gated write clock signal is generated as a function of a write clock signal and a pong write enable signal, and the pong gated read clock signal is generated as a function of a read clock signal and a pong read enable signal.

21. The system of claim 18, wherein the pong multiplexer selectively provides one of the pong gated write clock signal and the pong gated read clock signal to the pong buffer in response to a first control signal, the first control signal indicating that the ping buffer has been written, the first control signal being synchronous to a read clock signal.

22. The system of claim 18, wherein the ping multiplexer selectively provides one of the ping gated write clock signal and the ping gated read clock signal to the ping buffer in response to a first control signal, the first control signal indicating that the pong buffer has been written, the first control signal being synchronous to a read clock signal.

23. The system of claim 18, further comprising a read synchronizer, the read synchronizer providing a first control signal based on a ping buffer written signal, the first control signal being synchronous to a read clock signal, the ping buffer written signal being synchronous to a write clock signal, the first control signal and the ping buffer written signal indicating that the ping buffer has been written, the read synchronizer providing a second control signal based on a pong buffer written signal, the second control signal being synchronous to the read clock signal, the pong buffer written signal being synchronous to the write clock signal, the second control signal and the pong buffer written signal indicating that the pong buffer has been written.

24. The system of claim 18, further comprising a write synchronizer, the write synchronizer providing a first control signal using a ping buffer read signal, the first control signal being synchronous to a write clock signal, the ping buffer read signal being synchronous to a read clock signal, the first control signal and the ping buffer read signal indicating that the ping buffer has been read, the write synchronizer providing a second control signal using a pong buffer read signal, the second control signal being synchronous to the write clock signal, the pong buffer read signal being synchronous to the read clock signal, the second control signal and the pong buffer read signal indicating that the pong buffer has been read.

25. The system of claim 18, wherein at least one of the first single-port memory device and the second single-port memory device comprises a static random access memory.
